(19) United States
(12) Patent Application Publication
(10) Pub. No.: US 2023/0154765 A1
(43) Pub. Date: May 18, 2023

(54) Oxygen-Free Protection Layer Formation in Wafer Bonding Process

(71) Applicant: Taiwan Semiconductor Manufacturing Co., Ltd., Hsinchu (TW)

(72) Inventors: Chia Cheng Chou, Keelung City (TW); Chung-Chi Ko, Nantou (TW); Tze-Liang Lee, Hsinchu (TW)

(21) Appl. No.: 17/651,329

(22) Filed: Feb. 16, 2022

Related U.S. Application Data
(60) Provisional application No. 63/278,591, filed on Nov. 12, 2021.

(51) Int. Cl. H01L 21/56; H01L 21/768; H01L 21/02; H01L 21/48

(52) U.S. Cl. CPC H01L 21/56; H01L 21/76898; H01L 21/02164; H01L 21/0217; H01L 21/4857; H01L 21/486; H01L 2225/1041; H01L 2225/1058; H01L 25/105

(57) ABSTRACT

A method includes bonding a first wafer to a second wafer, and performing a trimming process on the first wafer. An edge portion of the first wafer is removed. After the trimming process, the first wafer has a first sidewall laterally recessed from a second sidewall of the second wafer. A protection layer is deposited and contacting a sidewall of the first wafer, which deposition process includes depositing a non-oxygen-containing material in contact with the first sidewall. The method further includes removing a horizontal portion of the protection layer that overlaps the first wafer, and forming an interconnect structure over the first wafer. The interconnect structure is electrically connected to integrated circuit devices in the first wafer.

### PRIORITY CLAIM AND CROSS-REFERENCE

This application claims the benefit of the following provisionally filed U.S. Patent application: Application No. 63/278,591, filed on Nov. 12, 2021, and entitled “ELK Moisture Free Approach for Device Performance Improvement,” which application is hereby incorporated herein by reference.

### BACKGROUND

Carrier wafers are commonly used in the packaging of integrated circuits as a supporting mechanism. For example, when forming a device wafer with through-vias penetrating through a substrate of the device wafer, the device wafer is bonded to a carrier wafer, so that the device wafer may be thinned, and electrical connectors may be formed on the backside of the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11 illustrate the intermediate stages in a wafer bonding process and the formation of a package in accordance with some embodiments.

FIGS. 12-14 illustrate the intermediate stages in a wafer bonding process and the formation of a package in accordance with some embodiments.

FIG. 15 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, a device wafer is bonded to a carrier wafer. The device wafer is thinned, followed by an edge trimming process. A protection layer is formed on the sidewall of the device wafer. In accordance with some embodiments, the protection layer comprises a non-oxygen-containing layer such as a silicon nitride layer. The protection layer may further be a bi-layer including the non-oxygen-containing layer, and a layer having good moisture-isolation ability. With the using of the non-oxygen-containing layer, the oxidation to the low-k dielectric layers and metal features in the low-k dielectric layers is reduced, and the device degradation caused by the oxidation is avoided. The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

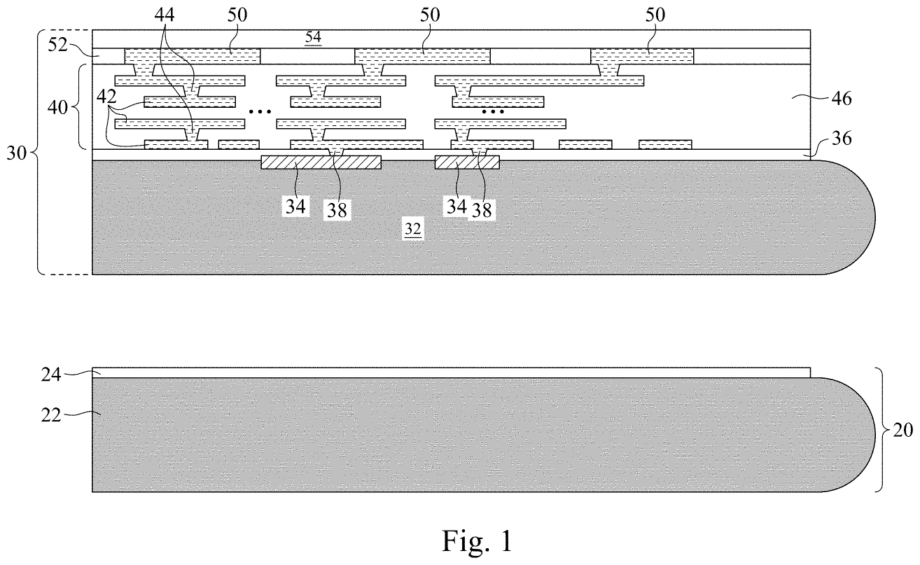

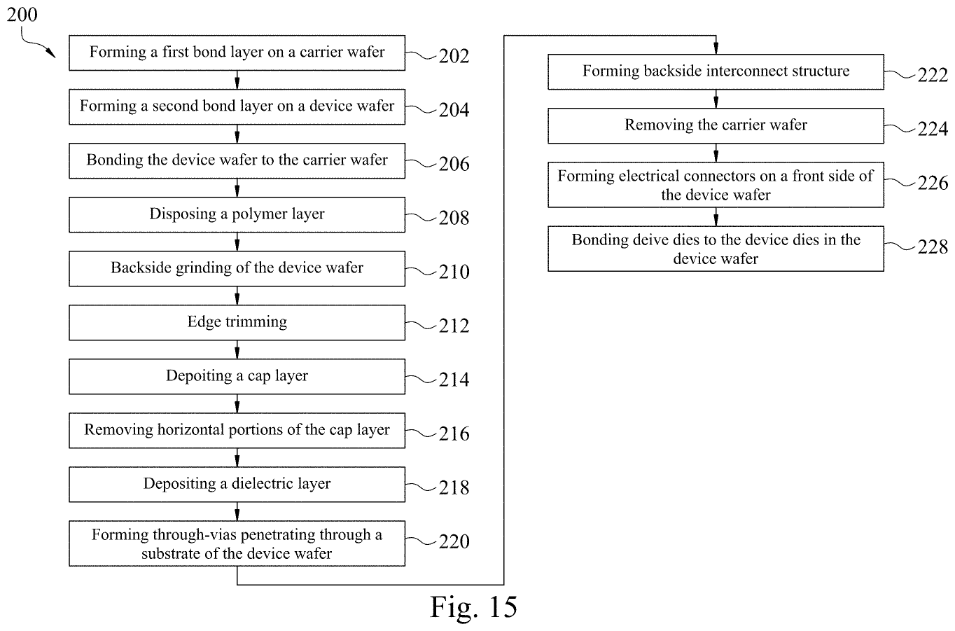

FIGS. 1-11 illustrate the cross-sectional views of intermediate stages in the bonding of a device wafer to a carrier wafer, and the formation of backside interconnect structure on the backside of the device wafer in accordance with some embodiments of the present disclosure. The corresponding processes are also reflected schematically in the process flow shown in FIG. 15.

Referring to FIG. 1, wafer 20 is formed. In accordance with some embodiments, wafer 20 is a carrier wafer, and hence is referred to as carrier wafer 20. Carrier wafer 20 may have a round top view shape. In accordance with some embodiments, carrier wafer 20 includes substrate 22. Substrate 22 may be formed of a same material as the substrate 32 in device wafer 30 (discussed subsequently), so that in the subsequent packaging process, the warpage due to the mismatch of Coefficients of Thermal Expansion (CTE) values between carrier wafer 20 and device wafer 30 is reduced. Substrate 22 may be formed of or comprise silicon, while other materials such as ceramic, glass, silicate glass, or the like, may also be used. In accordance with some embodiments, the entire substrate 22 is formed of a homogeneous material, with no other material different from the homogeneous material therein. For example, the entire carrier wafer 20 may be formed of silicon (doped or undoped), and there is no metal region, dielectric region, etc., therein.

In accordance with alternative embodiments, wafer 20 is a device wafer including active devices (such as transistors) and/or passive devices (such as capacitors, resistors, inductors, and/or the like) therein. Wafer 20, when being a device wafer, may also be an un-sawed wafer including a semiconductor substrate continuously extending into all device dies in the wafer, or may be a reconstructed wafer including discrete device dies that are packaged in an encapsulant (such as a molding compound).

Bond layer 24 is deposited on substrate 22. The respective process is illustrated as process 202 in the process flow 200 as shown in FIG. 15. In accordance with some embodiments, bond layer 24 is formed of or comprises a dielectric material, which may be a silicon-based dielectric material such as silicon oxide (SiO₂), SiN, SiON, SiOCN, SiC, SiCN, or the like, or combinations thereof. In accordance with some embodiments, bond layer 24 has a thickness in a range between about 1000 Å and about 10,000 Å.

In accordance with some embodiments of the present disclosure, bond layer 24 is formed using High-Density Plasma Chemical Vapor Deposition (HDPCVD), Plasma Enhanced Chemical Vapor Deposition (PECVD), Chemical Vapor Deposition (CVD), Low-Pressure Chemical Vapor Deposition (LPCVD), Atomic Layer deposition (ALD), or the like.

In accordance with some embodiments, bond layer 24 is in physical contact with substrate 22. In accordance with alternative embodiments, carrier wafer 20 includes a plurality of layers (not shown) between bond layer 24 and substrate 22. For example, there may be an oxide-based layer formed of an oxide-based material (which may also be silicon oxide based) such as silicon oxide, phospho-silicate glass (PSG), borosilicate glass (BSG), boron-doped phospho silicate glass (BPSG), fluorine-doped silicate glass (FSG), or the like. There may also be a nitride-based layer formed of or comprising silicon nitride, while it may also be formed of or comprising other materials such as silicon oxynitride (SiON). In accordance with some embodiments of the present disclosure, the layers between substrate 22 and bond layer 24 may be formed using PECVD, CVD, LPCVD, ALD, or the like. There may also be alignment marks formed between bond layer 24 and substrate 22. The alignment marks may be formed as metal plugs, which may be formed through damascene processes.

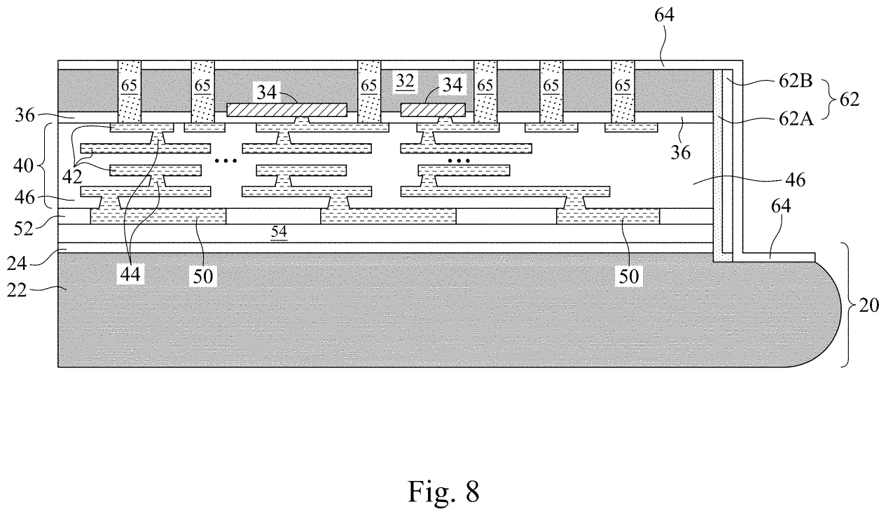

Further referring to FIG. 1, device wafer 30 is formed. device wafer 30 may be an un-sawed wafer, and the bonding process as shown in FIG. 8 is a wafer-to-wafer bonding process. In accordance with some embodiments, device wafer 30 includes substrate 32. There may be through-substrate vias (not shown) extending from the front side (the illustrated top side) into substrate 32. In accordance with alternative embodiments, no through-vias are formed at this stage, and the through-vias are formed in the process as shown in FIG. 8. Substrate 32 may be a semiconductor substrate such as a silicon substrate. In accordance with other embodiments, substrate 32 may include other semiconductor materials such as silicon germanium, carbon-doped silicon, or the like. Substrate 32 may be a bulk substrate, or may have a layered structure, for example, including a silicon substrate and a silicon germanium layer over the silicon substrate.

In accordance with some embodiments, device wafer 30 includes device dies, which may include logic dies, memory dies, input-output dies, Integrated Passive Devices (IPDs), or the like, or combinations thereof. For example, the logic device dies in device wafer 30 may be Central Processing Unit (CPU) dies, Graphic Processing Unit (GPU) dies, mobile application dies, Micro Control Unit (MCU) dies, BaseBand (BB) dies, Application processor (AP) dies, or the like. The memory dies in device wafer 30 may include Static Random-Access Memory (SRAM) dies, Dynamic Random-Access Memory (DRAM) dies, or the like. Device wafer 30 may be a simple device wafer including a semiconductor substrate extending continuously throughout device wafer 30, or may be a reconstructed wafer including device dies packaged therein, System-on-Chip (SoC) dies including a plurality of integrated circuits (or device dies) integrated as a system, or the like.

In accordance with some embodiments of the present disclosure, integrated circuit devices 34 are formed on the top surface of semiconductor substrate 32. Example integrated circuit devices 34 may include Complementary Metal-Oxide Semiconductor (CMOS) transistors, resistors, capacitors, diodes, and/or the like. The details of integrated circuit devices 34 are not illustrated herein. In accordance with alternative embodiments, device wafer 30 is used for forming interposers, in which substrate 32 may be a semiconductor substrate or a dielectric substrate.

Inter-Layer Dielectric (ILD) 36 is formed over semiconductor substrate 22, and fills the space between the gate stacks of transistors (not shown) in integrated circuit devices 34. In accordance with some example embodiments, ILD 36 is formed of or comprises silicon oxide, Phospho Silicate Glass (PSG), Boro Silicate Glass (BSG), Boron-Doped Phospho Silicate Glass (BPSG), Fluorine-Doped Silicate Glass (FSG), or the like. ILD 36 may be formed using spin coating, Flowable Chemical Vapor Deposition (FCVD), Chemical Vapor Deposition (CVD), or the like. In accordance with some embodiments of the present disclosure, ILD 36 is formed using a deposition method such as PECVD, LPCVD, or the like.

Contact plugs 38 are formed in ILD 36, and are used to electrically connect integrated circuit devices 34 to overlying metal lines and vias. In accordance with some embodiments of the present disclosure, contact plugs 38 are formed of a conductive material selected from tungsten, aluminum, copper, titanium, tantalum, titanium nitride, tantalum nitride, alloys therefore, and/or multi-layers thereof. The formation of contact plugs 38 may include forming contact openings in ILD 36, filling a conductive material(s) into the contact openings, and performing a planarization process (such as a Chemical Mechanical Polish (CMP) process) to level the top surfaces of contact plugs 38 with the top surface of ILD 36.

Over ILD 36 and contact plugs 38 resides interconnect structure 40. Interconnect structure 40 includes metal lines 42 and vias 44, which are formed in dielectric layers 46. Dielectric layers 46 may include Inter-Metal Dielectric (IMD) layers 46 hereinafter. In accordance with some embodiments of the present disclosure, some of dielectric layers 46 are formed of low-k dielectric materials having dielectric constant values (k-values) lower than about 3.0. Dielectric layers 46 may be formed of Black Diamond (a registered trademark of Applied Materials), a carbon-containing low-k dielectric material, Hydrogen SilsesQuioxane (HSQ), MethylSilsesQuioxane (MSQ), or the like. In accordance with some embodiments of the present disclosure, the formation of dielectric layers 46 includes depositing a porogen-containing dielectric material, and then performing a curing process to drive out the porogen, and hence the remaining dielectric layers 46 are porous. In accordance with alternative embodiments of the present disclosure, some or all of dielectric layers 46 are formed of non-low-k dielectric materials such as silicon oxide, silicon carbide (SiC), silicon carbo-nitride (SiCN), silicon oxy-carbo-nitride (SiOCN), or the like. Etch stop layers (not shown), which may be formed of silicon carbide, silicon nitride, silicon oxynitride, aluminum, oxide, aluminum nitride, or the like, or multi-layers thereof, are formed between dielectric layers 46, and are not shown for simplicity.

Metal lines 42 and vias 44 are formed in dielectric layers 46. The metal lines 42 at a same level are collectively referred to as a metal layer hereinafter. In accordance with some embodiments of the present disclosure, interconnect structure 40 includes a plurality of metal layers that are interconnected through vias 44. The number of IMD layers is determined based upon the routing requirement. For example, there may be between 5 and 15 IMD layers.

Metal lines 42 and vias 44 may be formed of copper or copper alloys, and they can also be formed of other metals. The formation process may include single damascene processes and dual damascene processes. In an example single damascene process, a trench is first formed in one of dielectric layers 46, followed by filling the trench with a conductive material(s). A planarization process such as a CMP process is then performed to remove the excess portions of the conductive material(s) higher than the top surface of the IMD layer, leaving a metal line in the trench. In a dual damascene process, both a trench and a via opening are formed in an IMD layer, with the via opening underlying and connected to the trench. The conductive material(s) is then filled into the trench and the via opening to form a metal line and a via, respectively. The conductive material(s) may include a diffusion barrier layer and a copper-containing metallic material over the diffusion barrier layer. The diffusion barrier layer may include titanium, titanium nitride, tantalum, tantalum nitride, or the like.

Dielectric layers 46 may further include passivation layers over the low-k dielectric layers. For example, there may be undoped silicate-glass (USG) layers, silicon oxide layers, silicon nitride layers, etc., over the damascene metal lines 42 and vias 44. The passivation layers are denser than the low-k dielectric layers, and have the function of isolating the low-k dielectric layers from detrimental chemicals and gases such as moisture.

In accordance with some embodiments, there may be top metal pads 50 formed over interconnect structure 40, and electrically connecting to integrated circuit devices 34 through metal lines 42 and vias 44. The top metal pads 50 may be formed of or comprise copper, nickel, titanium, palladium, or the like, or alloys thereof. In accordance with some embodiments, top metal pads 50 are in a passivation layer 52. In accordance with alternative embodiments, a polymer layer 52 (which may be polyimide, polybenzoxazole (PBO), or the like) may be formed, with the top metal pads 50 being in the polymer layer.

Bond layer 54 is deposited on the top of device wafer 30, and hence is a top surface layer of device wafer 30. The respective process is illustrated as process 204 in the process flow 200 as shown in FIG. 15. Bond layer 54 may be formed of a material selected from the same group of candidate materials for forming bond layer 24. For example, bond layer 54 may be selected from silicon oxide (SiO₂), SiN, SiON, SiOCN, SiC, SiCN, or the like, or combinations thereof. The material of bond layers 24 and 54 may be the same as each other or different from each other. In accordance with some embodiments, bond layer 54 has a thickness in a range between about 1,000 Å and about 10,000 Å.

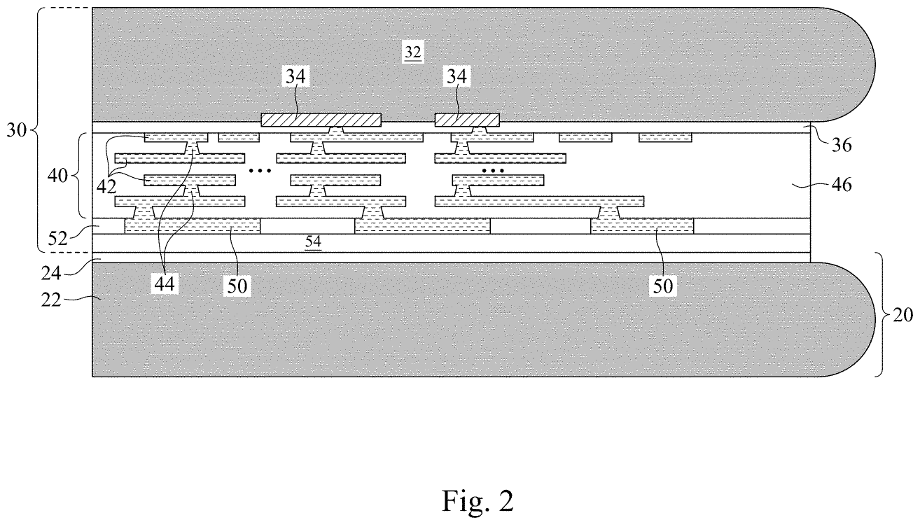

Referring to FIG. 2, device wafer 30 is flipped upside down, and bonded to carrier wafer 20, with bond layer 54 bonding to bond layer 24. The bonding may be performed through fusion bonding. The respective process is illustrated as process 206 in the process flow 200 as shown in FIG. 15. In accordance with some embodiments, the bonding of device wafer 30 to carrier wafer 20 includes pre-treating bond layers 24 and 54 in a process gas comprising oxygen (O₂) and/or nitrogen (N₂), performing a pre-bonding process to join bond layers 24 and 54 together, and performing an annealing process following the pre-bonding process. In accordance with some embodiments, during the pre-bonding process, device wafer 30 is put into contact with carrier wafer 20, with a pressing force applied to press device wafer 30 against carrier wafer 20.

After the pre-bonding process, an annealing process is performed. Si—O—Si bonds may be formed to join bond layers 24 and 54 together, so that bond layers 24 and 54 are bonded to each other with high bonding strength. In accordance with some embodiments, the annealing process is performed at a temperature between about 250° C. and about 400° C. The annealing duration may be in the range between about 30 minutes and about 60 minutes. In accordance with some embodiments, as shown in FIG. 2, device wafer 30 is over and bonded to the underlying carrier wafer 20. In accordance with alternative embodiments, device wafer 30 is underlying and bonded to the overlying carrier wafer 20, and after the bonding, the bonded structure is flipped, and the resulting structure is shown in FIG. 2.

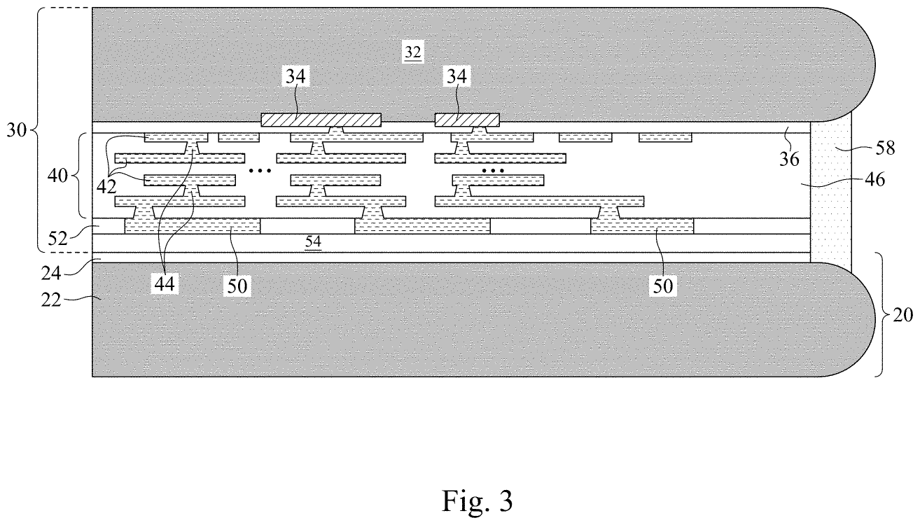

Referring to FIG. 3, a polymer layer 58 is dispensed into the gap between substrate 22 and substrate 32, and on the sidewalls of interconnect structure 40. The respective process is illustrated as process 208 in the process flow 200 as shown in FIG. 15. In accordance with some embodiments, polymer layer 58 is formed of or comprises polyimide, PBO, or the like. Polymer layer 58 is dispensed in a flowable form, and is then cured and solidified. Furthermore, polymer layer 58 is dispensed as a ring fully encircling the region between substrate 22 and substrate 32.

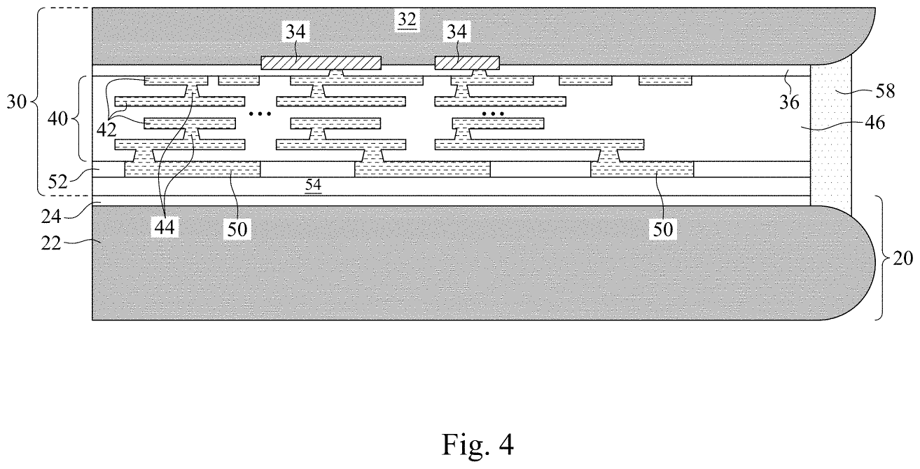

Referring to FIG. 4, a backside grinding process is performed from the backside of device wafer 30, and substrate 32 is thinned. The respective process is illustrated as process 210 in the process flow 200 as shown in FIG. 15. The backside grinding process may be performed through a CMP process or a mechanical polishing process. In the backside grinding process, polymer layer 58 has the function of preventing device wafer 30 from peeling off from carrier wafer 20. In addition, the grinding process and subsequent cleaning processes may involve the using of water, and polymer layer 58 can block moisture from penetrating into interconnect structure 40 from the sidewalls of dielectric layers 46, and may prevent the degradation of the dielectric layers and the metal features in device wafer 30.

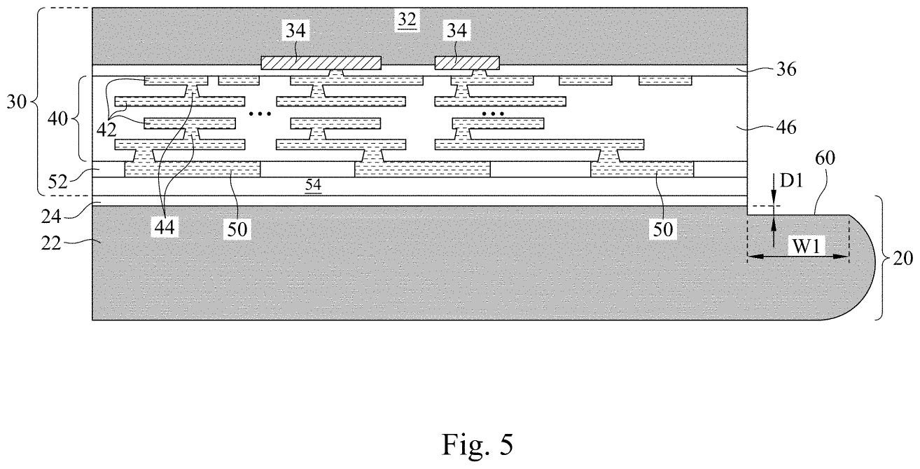

An edge trimming process is then performed to remove polymer layer 58 and the edge portions of device wafer 30. Some edge portions of carrier wafer 10 may also be removed. The respective process is illustrated as process 212 in the process flow 200 as shown in FIG. 15. The resulting structure is shown in FIG. 5, wherein a sidewall of wafer 30 is recessed laterally from the respective edge of wafer 20. In accordance with some embodiments, the trimmed width W1 may be in the range between about 2 mm and about 4 mm. Furthermore, in the trimming process, a top portion of the substrate 22 may be trimmed to form recess 60, which extends into substrate 22. The depth D1 of recess 60 may be in the range between about 50 μm and about 200 μm. Recess 60 forms a recess ring encircling the top portion of substrate 22.

In a subsequent process, substrate 32 may further be thinned. In accordance with alternative embodiments, the further thinning of substrate 32 is skipped. In accordance with some embodiments, substrate 32 is thinned in a dry etching process, which may be an anisotropic etching process or an isotropic etching process. In accordance with alternative embodiments, the etching may be performed through a dry etching process followed by a wet etching process. For example, the dry etching process may be performed using an etching gas including fluorine (F₂), Chlorine (Cl₂), hydrogen chloride (HCl), hydrogen bromide (HBr), Bromine (Br₂), C₂F₆, C_{F4}, SO₂, the mixture of HBr, Cl₂, and O₂, or the mixture of HBr, Cl₂, O₂, and CH₂F₂ etc. The wet etching process, if any, may be performed using KOH, tetramethylammonium hydroxide (TMAH), CH₃COOH, NH₄OH, H₂O₂, Isopropanol (IPA), the solution of HF, HNO₃, and H₂O, or the like.

In accordance with alternative embodiments, the thinning of substrate 32 may be performed through a CMP process or a mechanical grinding process. In the embodiments in which through-vias 65 (FIG. 8) have been formed previously to extend into semiconductor substrate 32, the through-vias 65 will be exposed by the thinning process.

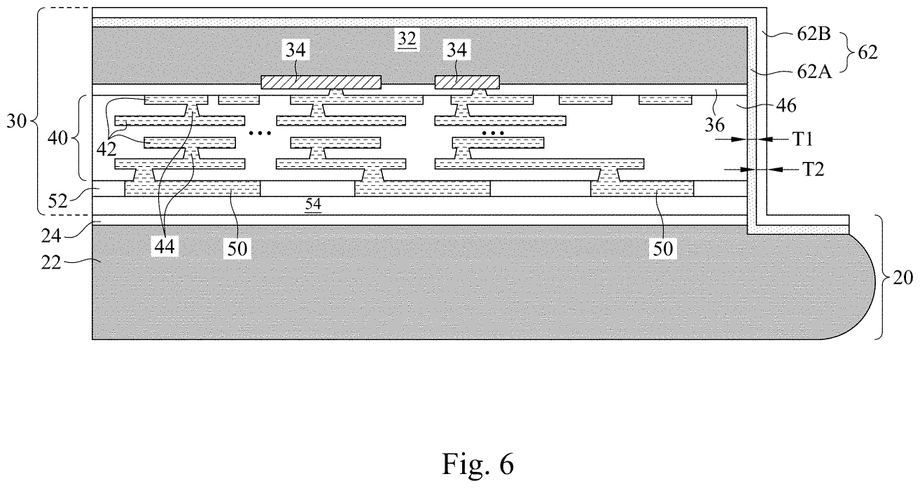

FIG. 6 illustrates the formation of protection layer 62, which is also an isolation layer. The respective process is illustrated as process 214 in the process flow 200 as shown in FIG. 15. In accordance with some embodiments, protection layer 62 comprises lower sub layer 62A, and may, or may not, include an upper sub layer 62B. Lower sub layer 62A, which is in physical contact with device wafer 30 and carrier wafer 20, is formed as an oxygen-free layer, which may be an oxygen-free dielectric layer. The precursors for forming lower sub layer 62A are also free from oxygen and water. In accordance with some embodiments, lower sub layer 62A is formed of or comprises SiN, SiC, SiCN, or the like.

The formation of lower sub layer 62A may include a conformal deposition process such as CVD, ALD, or the like. Accordingly, lower sub layer 62A is formed as a conformal layer, for example, with different portions of lower sub layer 62A having a variation smaller than about 20 percent. The thickness T1 of lower sub layer 62A may is great enough, so that it may act as a blocking layer to prevent oxygen and moisture from penetrating through it during the formation of upper sub layer 62B. In accordance with some embodiments, the thickness T1 of lower sub layer 62A may be greater than about 100 Å, and may be in the range between about 100 Å and about 1,000 Å. Lower sub layer 62A has good adhesion to wafers 20 and 30.

In accordance with some embodiments, upper sub layer 62B is deposited on lower sub layer 62A. Upper sub layer 62B is formed as an oxygen-containing layer, which may be an oxygen-containing dielectric layer. In accordance with some embodiments, upper sub layer 62B is formed of or comprises SiO₂, SiOC, SiON, SiOCN, or the like. The precursors for forming upper sub layer 62B may include a silicon-containing precursor such as silane, di-silane, or the like, and an oxygen-containing precursor such as O₂, ozone, or the like. The formation process may include a conformal deposition process such as CVD, ALD, or the like. Accordingly, upper sub layer 62B is formed as a conformal layer, for example, with different portions of upper sub layer 62B having a variation smaller than about 20 percent. The thickness T2 of upper sub layer 62B may be great enough, so that it may act as a blocking layer to prevent oxygen and moisture in outside environment from penetrating through it. In accordance with some embodiments, upper sub layer 62B may have thickness T2 greater than about 100 Å, and thickness T2 may be in the range between about 100 Å and about 1,000 Å.

Upper sub layer 62B, when being an oxygen-containing layer such as a silicon oxide layer, has good oxygen-blocking ability for blocking the oxygen and moisture in the air from reaching interconnect structure 40. On the other hand, the precursors for forming upper sub layer 62B may include oxygen, and hence the formation of upper sub layer 62B may cause the degradation of dielectric layers 46 and may oxidize the metal features in device wafer 30. Lower sub layer 62A is thus formed to prevent the oxygen-containing precursor in the formation of upper sub layer 62B from reaching device wafer 30. Accordingly, with the formation of the bi-layer protection layer 62, device wafer 30 is isolated from oxygen and moisture, both during and after the formation of isolation layer 62.

In accordance with some embodiments, each of lower sub layer 62A and upper sub layer 62B has a uniform composition, which means that when deposited, the atomic percentages of the elements in each of lower sub layer 62A and upper sub layer 62B are uniform. Accordingly, the flow rates of the corresponding precursors in each of lower sub layer 62A and upper sub layer 62B are uniform. In accordance with alternative embodiments, between upper sub layer 62B and lower sub layer 62A, a third (middle) sub layer is formed. The third sub layer has a gradually changed composition gradually transitioning from the composition of the lower sub layer 62A to the composition of the upper sub layer 62B. For example, when the lower sub layer 62A is a silicon nitride layer and the upper sub layer 62B is a silicon oxide layer, during the proceeding of the deposition of the third sub layer, in the deposition of the third sub layer, the flow rate of the nitrogen-containing precursor for depositing the lower sub layer 62A is gradually reduced, and the flow rate of the oxygen-containing precursor for depositing the upper sub layer 62B is gradually increased, until at a point, the nitrogen-containing precursor is turned off. Starting from this point, the upper sub layer 62B starts to be deposited.

In accordance with some embodiments, lower sub layer 62A has a lower oxygen atomic percentage and a higher nitrogen or carbon atomic percentage than upper sub layer 62B. Upper sub layer 62B has better isolation ability than lower sub layer 62A. In accordance with some embodiments, each of lower sub layer 62A and upper sub layer 62B may comprise SiOC or SiON, except that the oxygen atomic percentage in lower sub layer 62A is lower that in upper sub layer 62B.

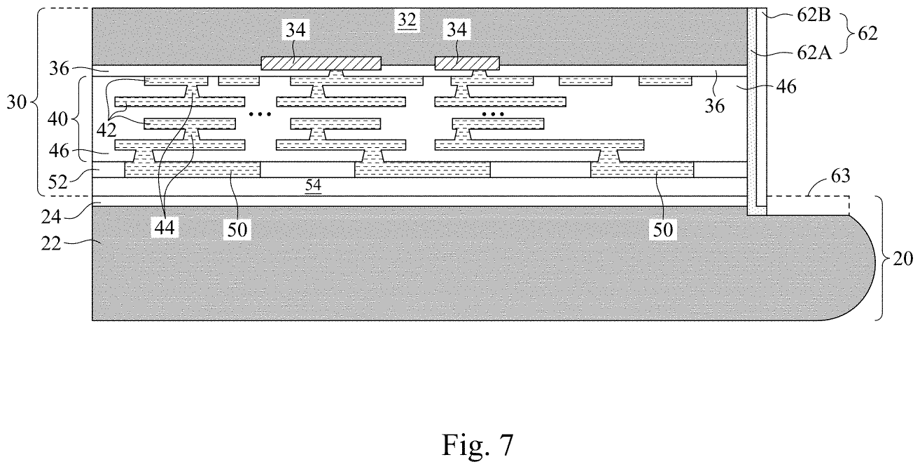

FIG. 7 illustrates the removal of the horizontal portions of protection layer 62, so that the top surface of device wafer 30 is exposed. The respective process is illustrated as process 216 in the process flow 200 as shown in FIG. 15. In accordance with some embodiments, a CMP process is performed to remove a first portion of protection layer 62 overlapping device wafer 30. An etching process may be performed to remove a second portion of protection layer 62 overlapping and contacting substrate 22 in carrier wafer 20. In accordance with alternative embodiments, the second portion of protection layer 62 is not removed, and is left on device wafer 20. Dashed region 63 is illustrated to show that the second portion of protection layer 62 may or may not exist in this region. In accordance with alternative embodiments, the removal of the horizontal portions of protection layer 62 is performed through one or a plurality of anisotropic etching processes. In accordance with these embodiments, both of the horizontal portions of protection layer 62 overlapping device wafer 30 and the horizontal portions of protection layer 62 overlapping carrier wafer 20 are removed.

The remaining protection layer 62 forms a full ring encircling, and contacting, device wafer 30. Protection layer 62 has the function of preventing the peeling of the layers in device wafer 30. Also, protection layer 62 prevent moisture and oxygen from penetrating into device wafer 30 from their sidewalls.

Referring to FIG. 8, dielectric layer 64 is formed, for example, in a conformal deposition process, which may be an ALD process, a CVD process, or the like. The respective process is illustrated as process 218 in the process flow 200 as shown in FIG. 15. In accordance with some embodiments, dielectric layer 64 is formed of or comprises silicon oxide, silicon nitride, silicon oxide, silicon oxynitride, or the like. Through-vias 65 may be formed to penetrate through substrate 32, and electrically connecting to integrated circuit devices 34. The formation process may include etching dielectric layer 64 and substrate 32 to form through-openings. The etching may be stopped on the metal pads in interconnect structure 40. Next, an isolation layer is formed to encircle each of the through-openings. The formation process may include depositing a conformal dielectric layer extending into the through-openings, and then performing an anisotropic etching process to re-expose the metal pads. A conductive material(s) is then deposited to fill the through-openings, followed by a planarization process to remove excess conductive materials outside of the through-openings. The remaining portions of the conductive material(s) are through-vias 65. The respective process is illustrated as process 220 in the process flow 200 as shown in FIG. 15.

In accordance with alternatively embodiments, the through-vias 65 have been formed previously (for example, in the process shown in FIG. 1). Accordingly, in the process shown in FIG. 8, a backside grinding process and etch-back process may be performed on substrate 32, so that the top portions of through-vias 65 protrude higher than the recessed top surface of substrate 32. Dielectric layer 64 is then deposited, followed by a light CMP process to re-expose through-vias 65.

As shown in FIG. 8, dielectric layer 64 extends on the outer sidewalls of protection layer 62. Dielectric layer 64 may further extend on and contacting the top surface of substrate 22. Conversely, dielectric layer 64 extends on, and contacting the top surface of, the horizontal portions of protection layer 62 in dashed region 63 (FIG. 7) when these portions of protection layer 62 are not removed.

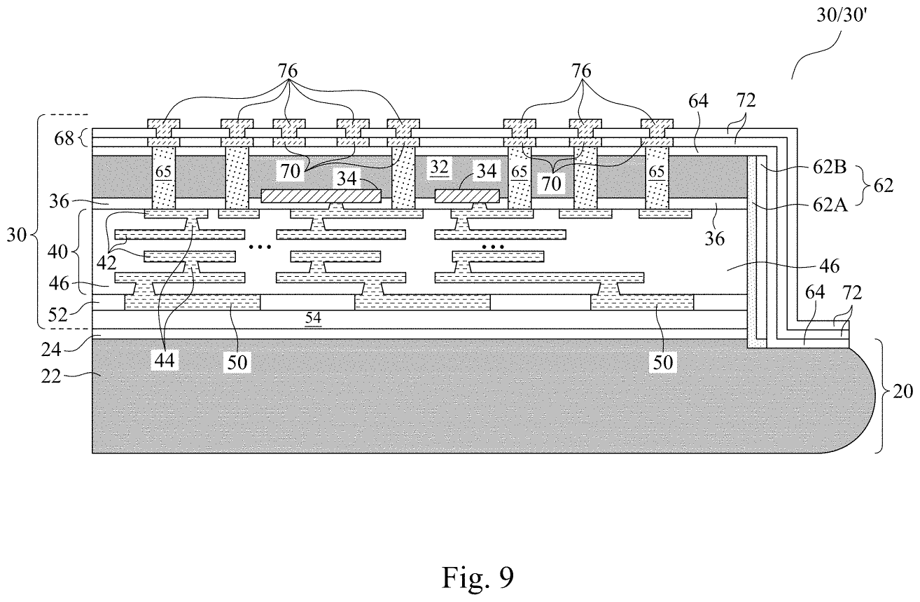

Referring to FIG. 9, backside interconnect structure 68 is formed, which includes one or a plurality of dielectric layers 72 and one or a plurality of layers of redistribution lines (RDLs) 70. The respective process is illustrated as process 222 in the process flow 200 as shown in FIG. 15. In accordance with some embodiments, RDLs 70 are formed through damascene processes, which includes depositing the corresponding dielectric layers 72, forming trenches and via openings in the dielectric layers 72, and filling the trenches and via openings with a metallic material(s) to form RDLs 70. Dielectric layers 72 may be formed of or comprise inorganic dielectric materials such as silicon oxide, silicon nitride, silicon oxynitride, or the like.

In accordance with alternative embodiments, dielectric layers 72 may be formed of polymers, which may be photo-sensitive, and the formation process of an RDL layer may include depositing a metal seed layer, forming and patterning a plating mask over the metal seed layer, performing a plating process to form the RDLs, removing the plating mask to expose the underlying portions of the metal seed layer, and etching the exposed portions of the metal seed layer.

In accordance with some embodiments, electrical connectors 76 are formed on the back surface of device wafer 30. Electrical connectors 76 may include metal bumps, metal pads, solder regions, or the like. In accordance with some embodiments, electrical connectors 76 protrude higher than the top surface of surface dielectric layer 72. In accordance with alternative embodiments, the top surface of electrical connectors 76 are coplanar with the surface dielectric layer 72.

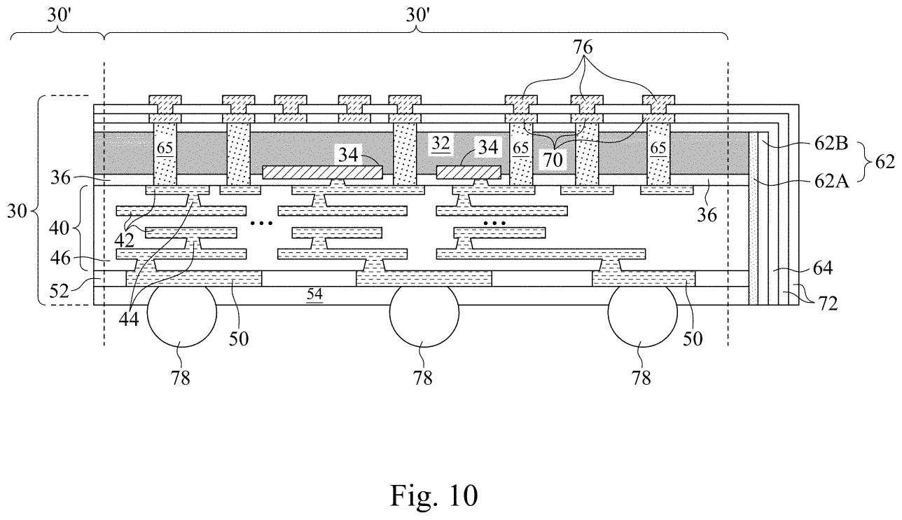

In accordance with some embodiments, carrier wafer 20 is removed. The respective process is illustrated as process 224 in the process flow 200 as shown in FIG. 15. In accordance with some embodiments, the top side of the structure shown in FIG. 9 is adhered to a tape, and the structure is flipped upside down. Substrate 22 is then removed, which may be through a CMP process, a mechanical grinding process, an etching process, or combinations thereof. Bond layer 24 may be removed, or may be left un-removed. When bond layer 24 is removed, bond layer 54 will be exposed. FIG. 10 illustrates a resulting structure.

As also shown in FIG. 10, electrical connectors 78 are formed on the front side of device wafer 30. The respective process is illustrated as process 226 in the process flow 200 as shown in FIG. 15. The formation process may include etching bond layer 54 to form openings, so that metal pads 50 are exposed, and forming electrical connectors 78 extending into the openings to electrically connect to metal pads 50.

In accordance with some embodiments, device wafer 30 may be singulated in a die-saw process to form discrete device dies 30′. Protection layer 62 is removed by the die-saw process, and does not exist in the resulting device dies 30′. In accordance with alternative embodiments, another device wafer is bonded to wafer 30 to form a reconstructed wafer, which is singulated to separate device dies 30′ from each other, with each of the device dies 30′ being bonded with one or a plurality of other device dies in the other device wafer.

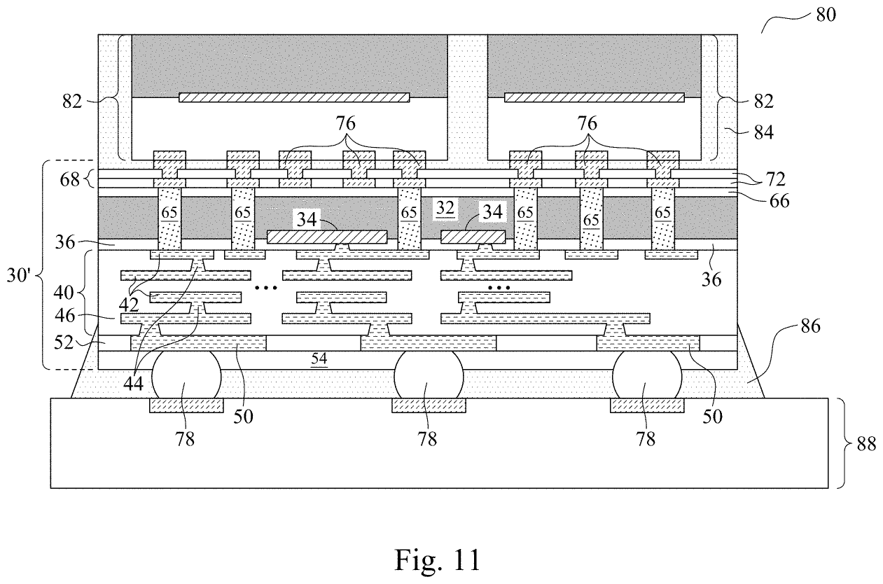

FIG. 11 illustrates a package 80 including device die 30′ bonded with device dies 82. The respective process is illustrated as process 228 in the process flow 200 as shown in FIG. 15. Encapsulant 84 may be dispensed to encapsulate device dies 82. Encapsulant 84 may be a molding compound, a molding underfill, or the, like. Package component 88 is bonded to device die 30′. Package component 88 may be a printed circuit board, a package substrate, or the like. Underfill 86 may be disposed between device die 30′ and package component 88.

In accordance with alternative embodiments, device dies 82, instead of being bonded to the device dies 30′ after the removal of substrate 22 (FIG. 9), are bonded to the device dies 30′ in un-sawed device wafer 30 before the removal of substrate 22. Accordingly, the device dies 82 as shown in FIG. 11 may be bonded to the structure shown in FIG. 9, followed by an encapsulation process to form a reconstructed wafer, which includes carrier wafer 20, device wafer 30, device dies 82, and encapsulant 84 (FIG. 11). The subsequent process may then be performed to form the structure shown in FIG. 11.

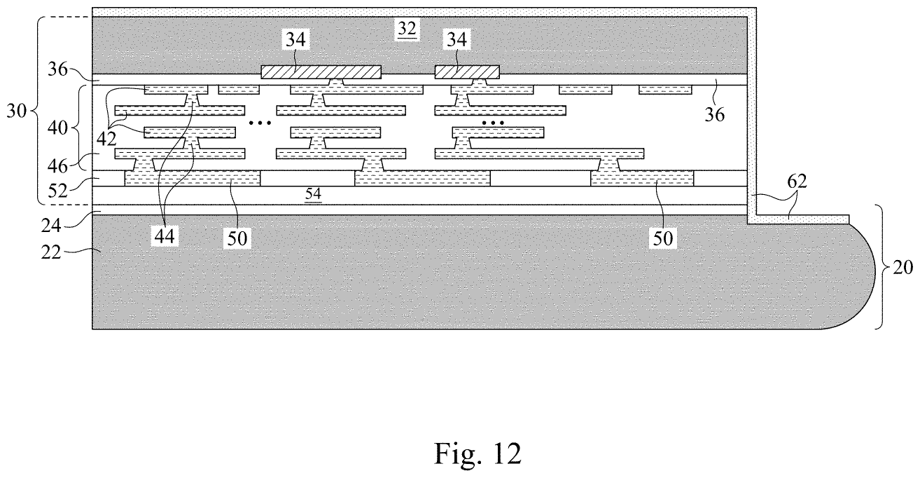

FIGS. 12 through 14 illustrate the cross-sectional views of intermediate stages in the formation of a package in accordance with alternative embodiments of the present disclosure. These embodiments are similar to the embodiments shown in FIGS. 1 through 11, except that protection layer 62 is a single layer. Unless specified otherwise, the materials and the formation processes of the components in these embodiments are essentially the same as the like components, which are denoted by like reference numerals in the preceding embodiments shown in FIGS. 1 through 11. The details regarding the formation processes and the materials of the components shown in FIGS. 12 through 14 may thus be found in the discussion of the preceding embodiments.

The initial processes of these embodiments are essentially the same as shown in FIGS. 1 through 5. Next, as shown in FIG. 12, protection layer 62 is deposited. In accordance with some embodiments, protection layer 62 is a homogeneous layer, with the entirety of protection layer 62 being formed of a homogeneous material. Protection layer 62 is formed of an oxygen-free material, with the precursors also being free from oxygen. For example, protection layer 62 may be formed using essentially the same method as for forming lower sub layer 62A (FIG. 6). With the formation of protection layer 62 being free from oxygen, in the formation of protection layer 62, there will be no oxygen-containing process gas penetrating into and degrading device wafer 30.

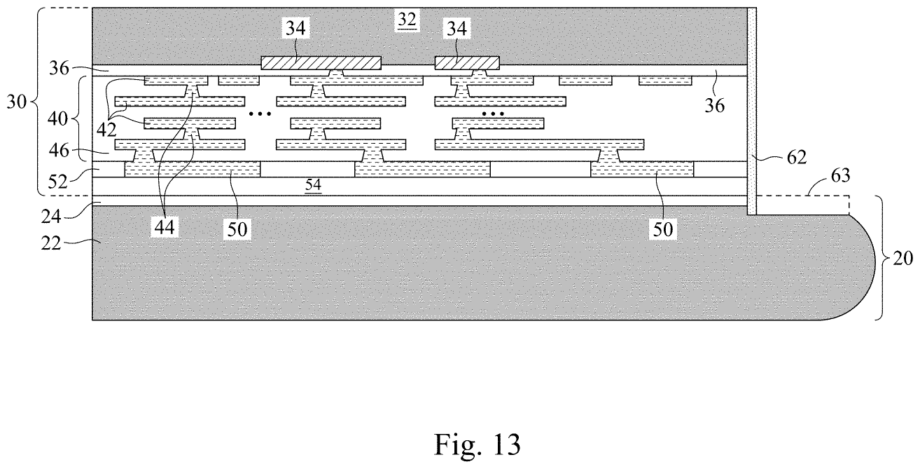

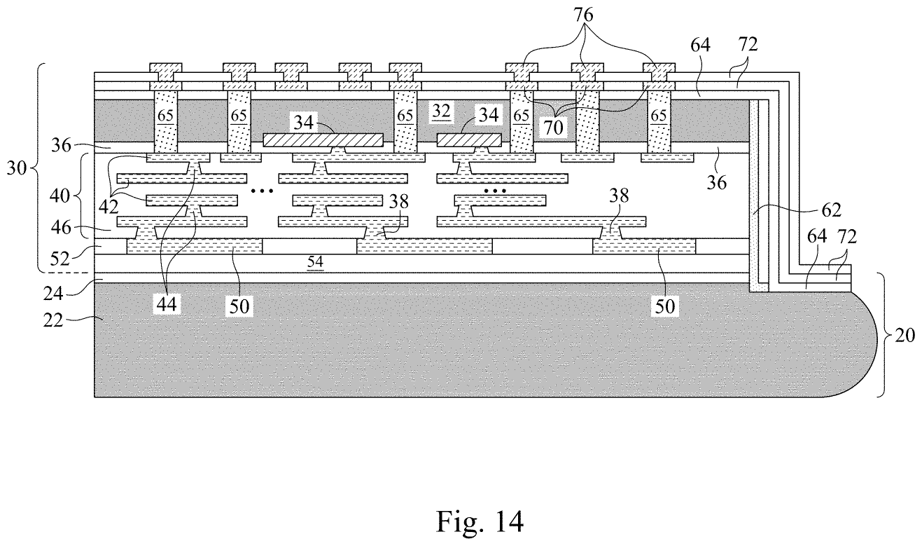

FIG. 13 illustrates the removal of the horizontal portions of protection layer 62, which may be through a planarization process, an anisotropic etching process, or both. FIG. 14 illustrates the formation of the backside interconnect structure on the backside of device wafer 30. The respective processes are essentially the same as discussed referring to FIG. 9. The subsequent processes are essentially the same as discussed referring to FIGS. 10 and 11, and are not repeated herein.

The embodiments of the present disclosure have some advantageous features. By forming a bi-layer protection layer or a multi-layer protection layer including two or more sub layers, the lower layer of the protection layer is free from oxygen, and its formation does not degrade the low-k dielectric layers and the metal features in the device wafer. The upper layer has good oxygen-and-moisture isolation ability, and may block oxygen and moisture from penetrating into the device wafer in subsequent processes. Accordingly, the oxygen-and-moisture isolation ability of the protection layer is improved.

In accordance with some embodiments of the present disclosure, a method comprises bonding a first wafer to a second wafer; performing a trimming process on the first wafer, wherein an edge portion of the first wafer is removed, and after the trimming process, the first wafer has a first sidewall laterally recessed from a second sidewall of the second wafer; depositing a protection layer contacting a sidewall of the first wafer, wherein the depositing the protection layer comprises depositing a non-oxygen-containing material in contact with the first sidewall; removing a horizontal portion of the protection layer that overlaps the first wafer; and forming an interconnect structure over the first wafer, wherein the interconnect structure is electrically connected to integrated circuit devices in the first wafer.

In an embodiment, the depositing the protection layer comprises depositing a first sub layer formed of the non-oxygen-containing material; and depositing a second sub layer on the first sub layer, wherein the second sub layer is formed of a material different from the non-oxygen-containing material. In an embodiment, the depositing the second sub layer comprises depositing an oxygen-containing material. In an embodiment, the depositing the first sub layer comprises depositing silicon nitride, and the depositing the second sub layer comprises depositing silicon oxide. In an embodiment, the method further comprises, between the depositing the first sub layer and the depositing the second sub layer, depositing a third sub layer, wherein during the depositing the third sub layer, process gases gradually transition from first process gases for depositing the first sub layer to second process gases for depositing the second sub layer.

In an embodiment, an entirety of the protection layer comprises the non-oxygen-containing material. In an embodiment, the method further comprises, after the interconnect structure is formed, removing the second wafer from the first wafer. In an embodiment, the method further comprises performing a singulation process on the first wafer to separate the first wafer into a plurality of device dies. In an embodiment, the plurality of device dies are free from remaining portions of the protection layer. In an embodiment, the protection layer is formed as a conformal layer. In an embodiment, the removing the horizontal portion of the protection layer comprises performing an anisotropic etching process. In an embodiment, the removing the horizontal portion of the protection layer comprises performing a polishing process.

In accordance with some embodiments of the present disclosure, a method comprises bonding a device wafer over a carrier wafer; thinning a semiconductor substrate of the device wafer; trimming the device wafer, wherein an edge portion of the device wafer is trimmed; depositing a protection layer on the device wafer and the carrier wafer, wherein the depositing the protection layer comprises depositing a first sub layer comprising a first material; and depositing a second sub layer comprising a second material different from the first material; revealing a top surface of the device wafer; and forming an interconnect structure over the device wafer, wherein the interconnect structure is electrically connected to integrated circuit devices in the device wafer.

In an embodiment, the first sub layer has a lower oxygen atomic percentage than the second sub layer. In an embodiment, the second sub layer has better oxygen-blocking ability than the first sub layer. In an embodiment, the method further comprises, after the protection layer is deposited, forming through-vias penetrating through the semiconductor substrate to electrically connect to conductive features underlying the semiconductor substrate. In an embodiment, the forming the interconnect structure comprises depositing a dielectric layer on the device wafer, wherein the dielectric layer extends on a sidewall of the protection layer.

In accordance with some embodiments of the present disclosure, a method comprises bonding a device wafer over a carrier wafer, wherein a first dielectric layer in the device wafer is bonded to a second dielectric layer in the carrier wafer; trimming the device wafer, wherein a portion of a first semiconductor substrate in the device wafer is trimmed, and a top surface of a second substrate in the carrier wafer is exposed; depositing a protection layer on the device wafer and the carrier wafer, wherein the depositing the protection layer is performed using process gases free from oxygen therein; removing horizontal portions of the protection layer from the device wafer and the carrier wafer; and removing the second substrate. In an embodiment, the depositing the protection layer comprises depositing a silicon nitride layer. In an embodiment, the depositing the protection layer further comprises depositing a silicon oxide layer over the silicon nitride layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
bonding a first wafer to a second wafer;
performing a trimming process on the first wafer, wherein an edge portion of the first wafer is removed, and after the trimming process, the first wafer has a first sidewall laterally recessed from a second sidewall of the second wafer;
depositing a protection layer contacting a sidewall of the first wafer, wherein the depositing the protection layer comprises depositing a non-oxygen-containing material in contact with the first sidewall;
removing a horizontal portion of the protection layer that overlaps the first wafer; and
forming an interconnect structure over the first wafer, wherein the interconnect structure is electrically connected to integrated circuit devices in the first wafer.

2. The method of claim 1, wherein the depositing the protection layer comprises:
depositing a first sub layer formed of the non-oxygen-containing material; and
depositing a second sub layer on the first sub layer, wherein the second sub layer is formed of a material different from the non-oxygen-containing material.

3. The method of claim 2, wherein the depositing the second sub layer comprises depositing an oxygen-containing material.

4. The method of claim 3, wherein the depositing the first sub layer comprises depositing silicon nitride, and the depositing the second sub layer comprises depositing silicon oxide.

5. The method of claim 2 further comprising, between the depositing the first sub layer and the depositing the second sub layer, depositing a third sub layer, wherein during the depositing the third sub layer, process gases gradually transition from first process gases for depositing the first sub layer to second process gases for depositing the second sub layer.

6. The method of claim 1, wherein an entirety of the protection layer comprises the non-oxygen-containing material.

7. The method of claim 1 further comprising, after the interconnect structure is formed, removing the second wafer from the first wafer.

8. The method of claim 1 further comprising performing a singulation process on the first wafer to separate the first wafer into a plurality of device dies.

9. The method of claim 8, wherein the plurality of device dies are free from remaining portions of the protection layer.

10. The method of claim 1, wherein the protection layer is formed as a conformal layer.

11. The method of claim 1, wherein the removing the horizontal portion of the protection layer comprises performing an anisotropic etching process.

12. The method of claim 1, wherein the removing the horizontal portion of the protection layer comprises performing a polishing process.

13. A method comprising:
bonding a device wafer over a carrier wafer;
thinning a semiconductor substrate of the device wafer;
trimming the device wafer, wherein an edge portion of the device wafer is trimmed;
depositing a protection layer on the device wafer and the carrier wafer, wherein the depositing the protection layer comprises:
depositing a first sub layer comprising a first material; and
depositing a second sub layer comprising a second material different from the first material;
revealing a top surface of the device wafer; and
forming an interconnect structure over the device wafer, wherein the interconnect structure is electrically connected to integrated circuit devices in the device wafer.

14. The method of claim 13, wherein the first sub layer has a lower oxygen atomic percentage than the second sub layer.

15. The method of claim 14, wherein the second sub layer has better oxygen-blocking ability than the first sub layer.

16. The method of claim 13 further comprising, after the protection layer is deposited, forming through-vias penetrating through the semiconductor substrate to electrically connect to conductive features underlying the semiconductor substrate.

17. The method of claim 13, wherein the forming the interconnect structure comprises depositing a dielectric layer on the device wafer, wherein the dielectric layer extends on a sidewall of the protection layer.

18. A method comprising:
bonding a device wafer over a carrier wafer, wherein a first dielectric layer in the device wafer is bonded to a second dielectric layer in the carrier wafer;
trimming the device wafer, wherein a portion of a first semiconductor substrate in the device wafer is trimmed, and a top surface of a second substrate in the carrier wafer is exposed;
depositing a protection layer on the device wafer and the carrier wafer, wherein the depositing the protection layer is performed using process gases free from oxygen therein;
removing horizontal portions of the protection layer from the device wafer and the carrier wafer; and
removing the second substrate.

19. The method of claim 18, wherein the depositing the protection layer comprises depositing a silicon nitride layer.

20. The method of claim 19, wherein the depositing the protection layer further comprises depositing a silicon oxide layer over the silicon nitride layer.
